(19) United States
(12) Patent Application Publication
(10) Pub. No.: US 2017/0345699 A1
(43) Pub. Date: Nov. 30, 2017

(54) SUPPORTING GLASS SUBSTRATE AND MANUFACTURING METHOD THEREFOR

(71) Applicant: Nippon Electric Glass Co., Ltd., Shiga (JP)

(72) Inventor: Hiroki KATAYAMA, Shiga (JP)

(73) Assignee: Nippon Electric Glass Co., Ltd., Shiga (JP)

(21) Appl. No.: 15/541,569

(22) PCT Filed: Dec. 21, 2015
(86) PCT No.: PCT/JP2015/085638

§ 371 Date: Jul. 5, 2017

(30) Foreign Application Priority Data
Jan. 5, 2015 (JP) 2015-000277

(51) Int. Cl. H01L 21/683; C03B 25/02; H01L 21/56; B32B 17/06; H01L 23/00; C03C 3/093; C03B 17/06

(52) U.S. Cl. CPC H01L 21/6835; H01L 24/11; C03B 25/025; C03C 3/093; H01L 21/561; H01L 21/568; B32B 17/06; H01L 24/96; C03B 17/064; H01L 2221/68359; H01L 2221/68386; H01L 2224/02379; H01L 2224/11002; H01L 2224/95001

(57) ABSTRACT

A technical object of the present invention is to devise a supporting glass substrate suitable for supporting a substrate to be processed to be subjected to high-density wiring and a method of manufacturing the supporting glass substrate, to thereby contribute to an increase in density of a semiconductor package. The supporting glass substrate of the present invention has a thermal shrinkage ratio of 20 ppm or less when a temperature of the supporting glass substrate is increased from room temperature to 400° C. at a rate of 5° C./minute, kept at 400° C. for 5 hours, and decrease to room temperature at a rate of 5° C./minute.

### TECHNICAL FIELD

The present invention relates to a supporting glass substrate and a method of manufacturing the supporting glass substrate, and more specifically, to a supporting glass substrate to be used for supporting a substrate to be processed in a manufacturing process for a semiconductor package, and a method of manufacturing the supporting glass substrate.

### BACKGROUND ART

Portable electronic devices, such as a cellular phone, a notebook-size personal computer, and a personal data assistance (PDA), are required to be downsized and reduced in weight. Along with this, a mounting space for semiconductor chips to be used in those electronic devices is strictly limited, and there is a problem of high-density mounting of the semiconductor chips. In view of this, in recent years, there has been an attempt to perform high-density mounting of a semiconductor package by a three-dimensional mounting technology, that is, by laminating semiconductor chips on top of another and connecting the semiconductor chips through wiring.

In addition, a conventional wafer level package (WLP) is manufactured by forming bumps into a wafer shape and dicing the wafer into chips. However, the conventional WLP has problems in that it is difficult to increase the number of pins, and chipping and the like of semiconductor chips are liable to occur because the semiconductor chips are mounted in a state in which the back surfaces thereof are exposed.

Therefore, as a new WLP, a fan-out type WLP has been proposed. In the fan-out type WLP, it is possible to increase the number of pins, and chipping and the like of semiconductor chips can be prevented by protecting end portions of the semiconductor chips.

The fan-out type WLP includes the step of molding a plurality of semiconductor chips with a sealing material of a resin, to thereby form a substrate to be processed, followed by arranging wiring on one surface of the substrate to be processed, the step of forming solder bumps, and the like.

Those steps involve heat treatment at about 300° C., and hence there is a risk in that the sealing material may be deformed, and the substrate to be processed may change in dimension. When the substrate to be processed changes in dimension, it becomes difficult to arrange wiring at high density on one surface of the substrate to be processed, and it is also difficult to form the solder bumps accurately.

### SUMMARY OF INVENTION

### Technical Problem

In order to suppress a change in dimension of a substrate to be processed, it is effective to use a glass substrate as a supporting substrate. The glass substrate is smoothened easily on the surface thereof and has stiffness. Accordingly, when the glass substrate is used, the substrate to be processed can be supported strongly and accurately. In addition, the glass substrate easily transmits light, for example, UV light. Accordingly, when the glass substrate is used, the substrate to be processed and the glass substrate can be easily fixed onto each other through formation of an adhesive layer or the like. In addition, the substrate to be processed and the glass substrate can also be easily separated from each other through formation of a peeling layer or the like.

However, even when the supporting glass substrate is used, it has been difficult to subject one of the surfaces of the substrate to be processed to high-density wiring in some cases.

The present invention has been made in view of the above-mentioned circumstances, and a technical object of the present invention is to devise a supporting glass substrate suitable for supporting a substrate to be processed to be subjected to high-density wiring, and a method of manufacturing the supporting glass substrate, to thereby contribute to an increase in density of a semiconductor package.

### Solution to Problem

The inventor of the present invention has repeatedly carried out various experiments. As a result, the inventor of the present invention has focused attention on the fact that the supporting glass substrate may be slightly thermally deformed due to heat treatment at about 300° C. in a manufacturing process for a semiconductor package, and this slight thermal deformation has an adverse effect on wiring accuracy of a substrate to be processed, and has found that the above-mentioned technical object can be achieved by reducing the thermal shrinkage amount of the supporting glass substrate to a predetermined value or less. Thus, the inventor of the present invention has proposed this finding as the present invention. That is, a supporting glass substrate according to one embodiment of the present invention has a thermal shrinkage ratio of 20 ppm or less when a temperature of the supporting glass substrate is increased from room temperature to 400° C. at a rate of 5° C./minute, kept at 400° C. for 5 hours, and decrease to room temperature at a rate of 5° C./minute. The “thermal shrinkage ratio” as used herein may be measured by the following method. First, a strip sample of 160 mm×30 mm is prepared as a sample for measurement (FIG. 1 (a)). Positions in the vicinity of from 20 mm to 40 mm from longitudinal ends of the strip sample G3 are marked with #1000 waterproof abrasive paper, and the strip sample G3 is cut by bending in a direction orthogonal to the markings, to thereby provide test pieces G31 and G32 (FIG. 1 (b)). Only the test piece G31 obtained by the cutting by bending is subjected to heat treatment under a predetermined condition, and the sample piece G31 that has not been subjected to heat treatment and the sample piece G32 that has been subjected to heat treatment are placed side by side and fixed with a tape T (FIG. 1 (c)). Then, positional shift amounts (ΔL1, ΔL2) of the markings are read with a laser microscope, and a thermal shrinkage ratio is calculated by the following numerical expression 1.

Thermal shrinkage ratio[ppm]=(ΔL1[μm]+ΔL2 [μm])/160×10⁻³

As described above, the heat treatment temperature in the manufacturing process for the semiconductor package is about 300° C., and it is difficult to evaluate the thermal shrinkage ratio of the supporting glass substrate through heat treatment at 300° C. Therefore, in the present invention, the thermal shrinkage ratio of the supporting glass substrate is evaluated under a heat treatment condition at 400° C. for 5 hours, and it is recognized that the thermal shrinkage ratio obtained in this evaluation has a correlation with the tendency of thermal shrinkage of the supporting glass substrate in the manufacturing process for the semiconductor package.

Secondly, it is preferred that the supporting glass substrate according to the embodiment of the present invention have a warpage level of 40 μm or less. The “warpage level” as used herein refers to the total of the absolute value of the maximum distance between the highest point and the least squares focal plane of the entire supporting glass substrate, and the absolute value of the lowest point and the least squares focal plane thereof, and may be measured with, for example, SBW-331ML/d manufactured by Kobelco Research Institute, Inc.

Thirdly, it is preferred that the supporting glass substrate according to the embodiment of the present invention have a total thickness variation of less than 2.0 μm. When the total thickness variation is decreased to less than 2.0 μm, the accuracy of processing treatment can be easily enhanced. In particular, wiring accuracy can be enhanced, and hence high-density wiring can be performed. In addition, the in-plane strength of the supporting glass substrate is improved, and hence the supporting glass substrate and the laminate are less liable to be broken. Further, the number of times of reuse (number of endurable uses) of the supporting glass substrate can be increased. Herein, the “total thickness variation” is a difference between the maximum thickness and the minimum thickness of the entire supporting glass substrate, and may be measured with, for example, SBW-331ML/d manufactured by Kobelco Research Institute, Inc.

Fourthly, it is preferred that the supporting glass substrate according to the embodiment of the present invention have a warpage level of less than 20 μm.

Fifthly, it is preferred that all or part of a surface of the supporting glass substrate according to the embodiment of the present invention comprise a polished surface.

Sixthly, it is preferred that the supporting glass substrate according to the embodiment of the present invention be formed by an overflow down-draw method.

Seventhly, it is preferred that the supporting glass substrate according to the embodiment of the present invention have a Young's modulus of 65 GPa or more. The term “Young's modulus” as used herein refers to a value obtained by measurement using a bending resonance method. 1 GPa is equivalent to about 101.9 Kgf/mm².

Eighthly, it is preferred that the supporting glass substrate according to the embodiment of the present invention have a contour of a wafer shape.

Ninthly, it is preferred that the supporting glass substrate according to the embodiment of the present invention be used for supporting a substrate to be processed in a manufacturing process for a semiconductor package.

Tenthly, it is preferred that the supporting glass substrate according to the embodiment of the present invention comprise a laminate including at least a substrate to be processed and a supporting glass substrate configured to support the substrate to be processed, the supporting glass substrate comprising the above-mentioned supporting glass substrate.

Eleventhly, a supporting glass substrate according to one embodiment of the present invention comprises the steps of: cutting a mother glass sheet to provide a supporting glass substrate; and heating the supporting glass substrate to a temperature equal to or more than an annealing point of the supporting glass substrate.

Twelfthly, it is preferred that in the supporting glass substrate according to the embodiment of the present invention, the heating be performed so that the supporting glass substrate has a thermal shrinkage ratio of 20 ppm or less when a temperature of the supporting glass substrate is increased from room temperature to 400° C. at a rate of 5° C./minute, kept at 400° C. for 5 hours, and decrease to room temperature at a rate of 5° C./minute.

Thirteenthly, it is preferred that in the supporting glass substrate according to the embodiment of the present invention, the heating be performed so that the supporting glass substrate has a warpage level of 40 μm or less.

Fourteenthly, it is preferred that the supporting glass substrate according to the embodiment of the present invention further comprise forming the mother glass sheet by an overflow down-draw method.

### BRIEF DESCRIPTION OF DRAWINGS

FIG. 1 are explanatory views for illustrating a measurement method for a thermal shrinkage ratio.

FIG. 2 is a conceptual perspective view for illustrating an example of a laminate of the present invention.

FIG. 3 are schematic sectional views for illustrating a manufacturing process for a fan-out type WLP.

FIG. 4 is a graph for showing a heating condition of a sample according to [Example 1].

FIG. 5 is a graph for showing a heating condition of a sample according to [Example 2].

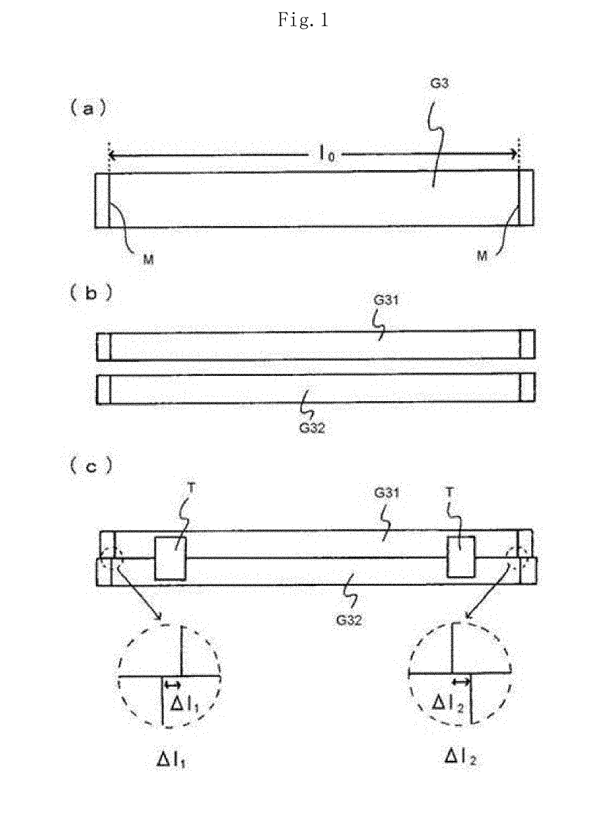

### DESCRIPTION OF EMBODIMENTS

A supporting glass substrate of the present invention has a thermal shrinkage ratio of 20 ppm or less, preferably 15 ppm or less, more preferably 12 ppm or less, still more preferably 10 ppm or less, particularly preferably 8 ppm or less when the temperature of the supporting glass substrate is increased from room temperature to 400° C. at a rate of 5° C./minute, kept at 400° C. for 5 hours, and decrease to room temperature at a rate of 5° C./minute. When the thermal shrinkage ratio is large, the supporting glass substrate is slightly thermally deformed due to heat treatment at about 300° C. in a manufacturing process for a semiconductor package, with the result that the accuracy of processing treatment does not decrease easily. In particular, the wiring accuracy decreases to make it difficult to perform high-density wiring. Further, it becomes difficult to increase the number of times of reuse (number of endurable uses) of the supporting glass substrate. As a method of reducing the thermal shrinkage ratio, there are given a method involving heating, a method involving increasing a strain point, and the like described later.

The supporting glass substrate of the present invention has a warpage level of preferably 40 μm or less, more preferably 30 μm or less, still more preferably 25 μm or less, yet still more preferably from 1 μm to 20 μm, particularly preferably from 5 μm to less than 20 μm. When the warpage level is large, the accuracy of processing treatment does not decrease easily. In particular, the wiring accuracy decreases to make it difficult to perform high-density wiring. Further, it becomes difficult to increase the number of times of reuse (number of endurable uses) of the supporting glass substrate.

The total thickness variation is preferably less than 2 μm, 1.5 μm or less, 1 μm or less, less than 1 μm, 0.8 μm or less, or from 0.1 μm to 0.9 μm, particularly preferably from 0.2 μm to 0.7 μm. When the total thickness variation is large, the accuracy of processing treatment does not decrease easily. In particular, the wiring accuracy decreases to make it difficult to perform high-density wiring. Further, it becomes difficult to increase the number of times of reuse (number of endurable uses) of the supporting glass substrate.

The arithmetic average roughness Ra of the surface is preferably 10 nm or less, 5 nm or less, 2 nm or less, or 1 nm or less, particularly preferably 0.5 nm or less. As the arithmetic average roughness Ra of the surface becomes smaller, the accuracy of the processing treatment can be enhanced easily. In particular, the wiring accuracy can be enhanced, and hence high-density wiring can be performed. The strength of the supporting glass substrate is improved, and hence the supporting glass substrate and the laminate are less liable to be broken. Further, the number of times of reuse (number of times of support) of the supporting glass substrate can be increased. The “arithmetic average roughness Ra” may be measured with an atomic force microscope (AFM).

It is preferred that all or part of a surface of the supporting glass substrate of the present invention be a polished surface. In terms of area ratio, it is more preferred that 50% or more of the surface be a polished surface, it is still more preferred that 70% or more of the surface be a polished surface, and it is particularly preferred that 90% or more of the surface be a polished surface. With this, the total thickness variation can be easily reduced, and the warpage level can also be easily reduced.

As a method for the polishing treatment, various methods may be adopted. However, a method involving sandwiching both surfaces of a supporting glass substrate with a pair of polishing pads and subjecting the supporting glass substrate to polishing treatment while rotating the supporting glass substrate and the pair of polishing pads together is preferred. Further, it is preferred that the pair of polishing pads have different outer diameters, and it is preferred that the polishing treatment be performed so that part of the supporting glass substrate intermittently extends off the polishing pads during polishing. With this, the total thickness variation can be easily reduced, and the warpage level can also be easily reduced. In the polishing treatment, a polishing depth is not particularly limited, but the polishing depth is preferably 50 μm or less, 30 μm or less, or 20 μm or less, particularly preferably 10 μm or less. As the polishing depth becomes smaller, the productivity of the supporting glass substrate is improved.

The supporting glass substrate of the present invention preferably has a wafer shape (substantially perfectly circular shape), and the diameter thereof is preferably 100 mm or more and 500 mm or less, particularly preferably 150 mm or more and 450 mm or less. With this, the supporting glass substrate is easily applied to the manufacturing process for a semiconductor package. As necessary, the supporting glass substrate may be processed into the other shapes, for example, a rectangular shape.

In the supporting glass substrate of the present invention, the thickness is preferably less than 2.0 mm, 1.5 mm or less, 1.2 mm or less, 1.1 mm or less, or 1.0 mm or less, particularly preferably 0.9 mm or less. As the thickness becomes smaller, the mass of the laminate is reduced in weight, and hence a handling property is enhanced. Meanwhile, when the thickness is excessively small, the strength of the supporting glass substrate itself decreases, and hence the supporting glass substrate does not easily serve a function of a supporting substrate. Thus, the thickness is preferably 0.1 mm or more, 0.2 mm or more, 0.3 mm or more, 0.4 mm or more, 0.5 mm or more, or 0.6 mm or more, particularly preferably more than 0.7 mm.

It is preferred that the supporting glass substrate of the present invention have the following characteristics.

In the supporting glass substrate of the present invention, it is preferred that the average thermal expansion coefficient within a temperature range of from 30° C. to 380° C. be 0×10⁻⁷/° C. or more and 165×10⁻⁷/° C. or less. With this, the thermal expansion coefficients of the substrate to be processed and the supporting glass substrate are easily matched with each other. When the thermal expansion coefficients of the substrate to be processed and the supporting glass substrate are matched with each other, a change in dimension (in particular, warping deformation) of the substrate to be processed during the processing treatment is suppressed easily. As a result, wiring can be arranged at high density on one surface of the substrate to be processed, and solder bumps can also be formed thereon accurately. The “average thermal expansion coefficient within a temperature range of from 30° C. to 380° C.” may be measured with a dilatometer.

It is preferred that the average thermal expansion coefficient within a temperature range of from 30° C. to 380° C. be increased when the ratio of the semiconductor chips within the substrate to be processed is small and the ratio of the sealing material within the substrate to be processed is large. Meanwhile, it is preferred that the average thermal expansion coefficient be decreased when the ratio of the semiconductor chips within the substrate to be processed is large and the ratio of the sealing material within the substrate to be processed is small.

When the average thermal expansion coefficient within a temperature range of from 30° C. to 380° C. is set to 0×10⁻⁷/° C. or more and less than 50×10⁻⁷/° C., the supporting glass substrate preferably comprises as a glass composition, in terms of mass %, 55% to 75% of SiO₂, 15% to 30% of Al₂O₃, 0.1% to 6% of Li₂O, 0% to 8% of Na₂O+K₂O, and 0% to 10% of MgO+CaO+SrO+BaO, or preferably comprises 55% to 75% of SiO₂, 10% to 30% of Al₂O₃, 0% to 0.3% of Li₂O+Na₂O+K₂O, and 5% to 20% of MgO+CaO+SrO+BaO. When the average thermal expansion coefficient within a temperature range of from 30° C. to 380° C. is set to 50×10⁷/° C. or more and less than 75×10⁻⁷/° C., the supporting glass substrate preferably comprises as a glass composition, in terms of mass %, 55% to 70% of SiO₂, 3% to 15% of Al₂O₃, 5% to 20% of B₂O₃, 0% to 5% of MgO, 0% to 10% of CaO, 0% to 5% of SrO, 0% to 5% of BaO, 0% to 5% of ZnO, 5% to 15% of Na₂O, and 0% to 10% of K₂O. When the average thermal expansion coefficient within a temperature range of from 30° C. to 380° C. is set to 75×10⁻⁷/° C. or more and 85×10⁻⁷/° C. or less, the supporting glass substrate preferably comprises as a glass composition, in terms of mass %, 60% to 75% of SiO₂, 5% to 15% of Al₂O₃, 5% to 20% of B₂O₃, 0% to 5% of MgO, 0% to 10% of CaO, 0% to 5% of SrO, 0% to 5% of BaO, 0% to 5% of ZnO, 7% to 16% of Na₂O, and 0% to 8% of K₂O. When the average thermal expansion coefficient within a temperature range of from 30° C. to 380° C. is set to more than 85×10⁻⁷/° C. and 120×10⁻⁷/° C. or less, the supporting glass substrate preferably comprises as a glass composition, in terms of mass %, 55% to 70% of SiO₂, 3% to 13% of Al₂O₃, 2% to 8% of B₂O₃, 0% to 5% of MgO, 0% to 10% of CaO, 0% to 5% of SrO, 0% to 5% of BaO, 0% to 5% of ZnO, 10% to 21% of Na₂O, and 0% to 5% of K₂O. When the average thermal expansion coefficient within a temperature range of from 30° C. to 380° C. is set to more than 120×10⁻⁷/° C. and 165×10⁻⁷/° C. or less, the supporting glass substrate preferably comprises as a glass composition, in terms of mass %, 53% to 65% of SiO₂, 3% to 13% of Al₂O₃, 0% to 5% of B₂O₃, 0.1% to 6% of MgO, 0% to 10% of CaO, 0% to 5% of SrO, 0% to 5% of BaO, 0% to 5% of ZnO, 20% to 40% of Na₂O+K₂O, 12% to 21% of Na₂O, and 7% to 21% of K₂O. With this, the thermal expansion coefficient is regulated easily within a desired range, and devitrification resistance is enhanced. Therefore, a supporting glass substrate having a small total thickness variation is formed easily.

The strain point is preferably 480° C. or more, more preferably 500° C. or more, still more preferably 510° C. or more, yet still more preferably 520° C. or more, particularly preferably 530° C. or more. As the strain point becomes higher, the thermal shrinkage ratio is more easily reduced. The “strain point” as used herein refers to a value measured based on a method of ASTM C336.

The Young's modulus is preferably 65 GPa or more, 67 GPa or more, 68 GPa or more, 69 GPa or more, 70 GPa or more, 71 GPa or more, or 72 GPa or more, particularly preferably 73 GPa or more. When the Young's modulus is excessively low, it becomes difficult to maintain the stiffness of the laminate, and the deformation, warpage, and breakage of the substrate to be processed are liable to occur.

The liquidus temperature is preferably less than 1,150° C., 1,120° C. or less, 1,100° C. or less, 1,080° C. or less, 1,050° C. or less, 1,010° C. or less, 980° C. or less, 960° C. or less, or 950° C. or less, particularly preferably 940° C. or less. With this, a supporting glass substrate is formed easily by a down-draw method, in particular, an overflow down-draw method. Therefore, a supporting glass substrate having a small thickness is manufactured easily, and the thickness variation after forming can be reduced. Further, in a manufacturing process for the supporting glass substrate, a situation in which a devitrified crystal is generated to decrease the productivity of the supporting glass substrate is prevented easily. The “liquidus temperature” may be calculated by loading glass powder that has passed through a standard 30-mesh sieve (500 μm) and remained on a 50-mesh sieve (300 μm) into a platinum boat, then keeping the glass powder for 24 hours in a gradient heating furnace, and measuring a temperature at which crystals of glass are deposited.

The viscosity at a liquidus temperature is preferably 10^{4.6} dPa·s or more, 10^{5.6} dPa·s or more, 10^{5.2} dPa·s or more, 10^{5.4} dPa·s or more, or 10^{5.6} dPa·s or more, particularly preferably 10^{5.8} dPa·s or more. With this, a supporting glass substrate is formed easily by a down-draw method, in particular, an overflow down-draw method. Therefore, a supporting glass substrate having a small thickness is manufactured easily, and the thickness variation after forming can be reduced. Further, in a manufacturing process for the supporting glass substrate, a situation in which a devitrified crystal is generated to decrease the productivity of the supporting glass substrate is prevented easily. The “viscosity at a liquidus temperature” may be measured by a platinum sphere pull up method. The viscosity at a liquidus temperature is an indicator of formability. As the viscosity at a liquidus temperature becomes higher, the formability is enhanced.

The temperature at 10^{2.5} dPa·s is preferably 1,580° C. or less, 1,500° C. or less, 1,450° C. or less, 1,400° C. or less, or 1,350° C. or less, particularly preferably from 1,200° C. to 1,300° C. When the temperature at 10^{2.5} dPa·s increases, meltability is degraded, and the manufacturing cost of a supporting glass substrate rises. The “temperature at 10^{2.5} dPa·s” may be measured by the platinum sphere pull up method. The temperature at 10^{2.5} dPa·s corresponds to a melting temperature. As the melting temperature becomes lower, the meltability is enhanced.

The supporting glass substrate of the present invention is preferably formed by a down-draw method, in particular, an overflow down-draw method. The overflow down-draw method refers to a method in which a molten glass is caused to overflow from both sides of a heat-resistant, trough-shaped structure, and the overflowing molten glasses are subjected to down-draw downward at the lower end of the trough-shaped structure while being joined, to thereby form a mother glass sheet. When a supporting glass substrate is produced by the overflow down-draw method, surfaces that are to serve as the surfaces of the supporting glass substrate are formed in a state of free surfaces without being brought into contact with the trough-shaped refractory. Therefore, a supporting glass substrate having a small thickness is manufactured easily, and the total thickness variation can be reduced. As a result, the manufacturing cost of the supporting glass substrate can be reduced.

As a method of forming a mother glass sheet, besides the overflow down-draw method, for example, a slot down-draw method, a redraw method, a float method, a roll-out method, or the like may also be adopted.

It is preferred that the supporting glass substrate of the present invention have a polished surface on a surface thereof and be formed by the overflow down-draw method. With this, the total thickness variation before the polishing treatment is reduced, and hence the total thickness variation can be reduced to the extent possible through the polishing treatment. The total thickness variation can be reduced to, for example, 1.0 μm or less.

From the viewpoint of reducing the warpage level, it is preferred that the supporting glass substrate of the present invention be subjected to no chemical tempering treatment. Meanwhile, from the viewpoint of mechanical strength, it is preferred that the supporting glass substrate be subjected to chemical tempering treatment. That is, from the viewpoint of reducing the warpage level, it is preferred that the supporting glass substrate have no compressive stress layer in the surface thereof, and from the viewpoint of mechanical strength, it is preferred that the supporting glass substrate have a compressive stress layer in the surface thereof.

A method of manufacturing a supporting glass substrate of the present invention comprises the steps of: cutting a mother glass sheet to provide a supporting glass substrate; and heating the obtained supporting glass substrate to a temperature equal to or more than (an annealing point of the supporting glass substrate). Here, the technical features (preferred configuration and effects) of the method of manufacturing a supporting glass substrate of the present invention overlap the technical features of the supporting glass substrate of the present invention. Thus, the details of the overlapping portions are omitted in this description.

The method of manufacturing a supporting glass substrate of the present invention comprises the step of cutting a mother glass sheet to provide a supporting glass substrate. As a method of cutting the mother glass sheet, various methods may be adopted. For example, a method of cutting a mother glass sheet through thermal shock during laser irradiation, and a method involving subjecting a mother glass sheet to scribing and cutting the resultant by bending are available.

The method of manufacturing a supporting glass substrate of the present invention comprises the step of heating the supporting glass substrate to a temperature equal to or more than (an annealing point of the supporting glass substrate). Such heating step may be performed through use of a known electric furnace, gas furnace, or the like.

The supporting glass substrate is heated preferably at a temperature equal to or more than an annealing point, more preferably at a temperature equal to or more than (the annealing point+30° C.), still more preferably at a temperature equal to or more than (the annealing point+50° C.). When the heating temperature is low, the thermal shrinkage ratio of the supporting glass substrate is not reduced easily. Meanwhile, the supporting glass substrate is heated preferably at a temperature equal to or less than a softening point, more preferably at a temperature equal to or less than (the softening temperature—50° C.), still more preferably at a temperature equal to or less than (the softening point—80° C.). When the heating temperature is excessively high, the dimensional accuracy of the supporting glass substrate is liable to decrease.

In the method of manufacturing a supporting glass substrate of the present invention, it is preferred that the heating be performed so that the supporting glass substrate has a warpage level of 40 μm or less. Further, it is preferred that the heating be performed under a state in which the supporting glass substrate is sandwiched between heat-resistant substrates. With this, the warpage level of the supporting glass substrate can be reduced. As the heat-resistant substrates, a mullite substrate, an alumina substrate, and the like may be used. Further, when the heating is performed at a temperature equal to or more than the annealing point, the warpage level and the thermal shrinkage amount of the supporting glass substrate can be reduced simultaneously.

It is also preferred that the heating be performed under a state in which a plurality of supporting glass substrates are laminated. With this, the warpage level of the supporting glass substrate laminated in a lower portion of the laminate is properly reduced by the mass of the supporting glass substrate laminated in an upper portion of the laminate.

It is preferred that the method of manufacturing a supporting glass substrate of the present invention further comprise the step of polishing the surface of the supporting glass substrate so that the total thickness variation of the supporting glass substrate is less than 2.0 μm, and the preferred mode of this step is as described above.

The laminate of the present invention has a feature of comprising at least a substrate to be processed and a supporting glass substrate configured to support the substrate to be processed, the supporting glass substrate comprising the above-mentioned supporting glass substrate. Here, the technical features (preferred configuration and effects) of the laminate of the present invention overlap the technical features of the supporting glass substrate of the present invention. Thus, the details of the overlapping portions are omitted in this description.

It is preferred that the laminate of the present invention comprise an adhesive layer between the substrate to be processed and the supporting glass substrate. It is preferred that the adhesive layer be formed of a resin, and for example, a thermosetting resin, a photocurable resin (in particular, a UV-curable resin), and the like are preferred. It is preferred that the adhesive layer have heat resistance that withstands the heat treatment in the manufacturing process for a semiconductor package. With this, the adhesive layer is less liable to be melted in the manufacturing process for a semiconductor package, and the accuracy of the processing treatment can be enhanced.

It is preferred that the laminate of the present invention further comprise a peeling layer between the substrate to be processed and the supporting glass substrate, more specifically, between the substrate to be processed and the adhesive layer, or further comprise a peeling layer between the supporting glass substrate and the adhesive layer. With this, after the substrate to be processed is subjected to predetermined processing treatment, the substrate to be processed is easily peeled from the supporting glass substrate. From the viewpoint of productivity, it is preferred that the substrate to be processed be peeled through laser irradiation or the like.

The peeling layer is formed of a material in which “in-layer peeling” or “interfacial peeling” occurs through laser irradiation or the like. That is, the peeling layer is formed of a material in which the interatomic or intermolecular binding force between atoms or molecules is lost or reduced to cause ablation or the like, to thereby cause peeling, through irradiation with light having predetermined intensity. There are the case where components contained in the peeling layer turn into a gas to be released, to thereby cause separation, through irradiation with light, and the case where the peeling layer absorbs light to turn into a gas and the vapor thereof is released, to thereby cause separation.

In the laminate of the present invention, it is preferred that the supporting glass substrate be larger than the substrate to be processed. With this, even when the center positions of the substrate to be processed and the supporting glass substrate are slightly separated from each other at a time when the substrate to be processed and the supporting glass substrate are supported, an edge portion of the substrate to be processed is less liable to extend off from the supporting glass substrate.

A method of manufacturing a semiconductor package according to the present invention has a feature of comprising the steps of: preparing a laminate including at least a substrate to be processed and a supporting glass substrate configured to support the substrate to be processed; and subjecting the substrate to be processed to processing treatment, the supporting glass substrate comprising the above-mentioned supporting glass substrate. Here, the technical features (preferred configuration and effects) of the method of manufacturing a semiconductor package according to the present invention overlap the technical features of the supporting glass substrate and laminate of the present invention. Thus, the details of the overlapping portions are omitted in this description.

The method of manufacturing a semiconductor package according to the present invention comprises the step of preparing a laminate including at least a substrate to be processed and a supporting glass substrate configured to support the substrate to be processed. The laminate including at least a substrate to be processed and a supporting glass substrate configured to support the substrate to be processed has the above-mentioned material construction.

It is preferred that the method of manufacturing a semiconductor package according to the present invention further comprise the step of conveying the laminate. With this, the treatment efficiency of the processing treatment can be enhanced. The “step of conveying the laminate” and the “step of subjecting the substrate to be processed to processing treatment” are not required to be performed separately, and may be performed simultaneously.

In the method of manufacturing a semiconductor package according to the present invention, it is preferred that the processing treatment be treatment involving arranging wiring on one surface of the substrate to be processed or treatment involving forming solder bumps on one surface of the substrate to be processed. In the method of manufacturing a semiconductor package according to the present invention, during the processing treatment, the supporting glass substrate and the substrate to be processed are less liable to be changed in dimension, and hence those steps can be performed properly.

Besides the foregoing, the processing treatment may be any of treatment involving mechanically polishing one surface (in general, the surface on an opposite side to the supporting glass substrate) of the substrate to be processed, treatment involving subjecting one surface (in general, the surface on an opposite side to the supporting glass substrate) of the substrate to be processed to dry etching, and treatment involving subjecting one surface (in general, the surface on an opposite side to the supporting glass substrate) of the substrate to be processed to wet etching. In the method of manufacturing a semiconductor package of the present invention, thermal deformation or warpage is less liable to occur in the supporting glass substrate and the substrate to be processed, and the stiffness of the laminate can be maintained. As a result, the processing treatment can be performed properly.

The semiconductor package according to the present invention has a feature of being manufactured by the above-mentioned method of manufacturing a semiconductor package. Here, the technical features (preferred configuration and effects) of the semiconductor package of the present invention overlap the technical features of the supporting glass substrate, laminate, and method of manufacturing a semiconductor package of the present invention. Thus, the details of the overlapping portions are omitted in this description.

The electronic device according to the present invention has a feature of comprising a semiconductor package, the semiconductor package comprising the above-mentioned semiconductor package. Here, the technical features (preferred configuration and effects) of the electronic device of the present invention overlap the technical features of the supporting glass substrate, laminate, method of manufacturing a semiconductor package, and semiconductor package of the present invention. Thus, the details of the overlapping portions are omitted in this description.

The present invention is further described with reference to the drawings.

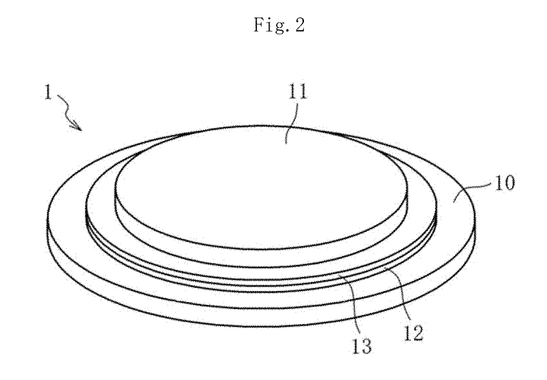

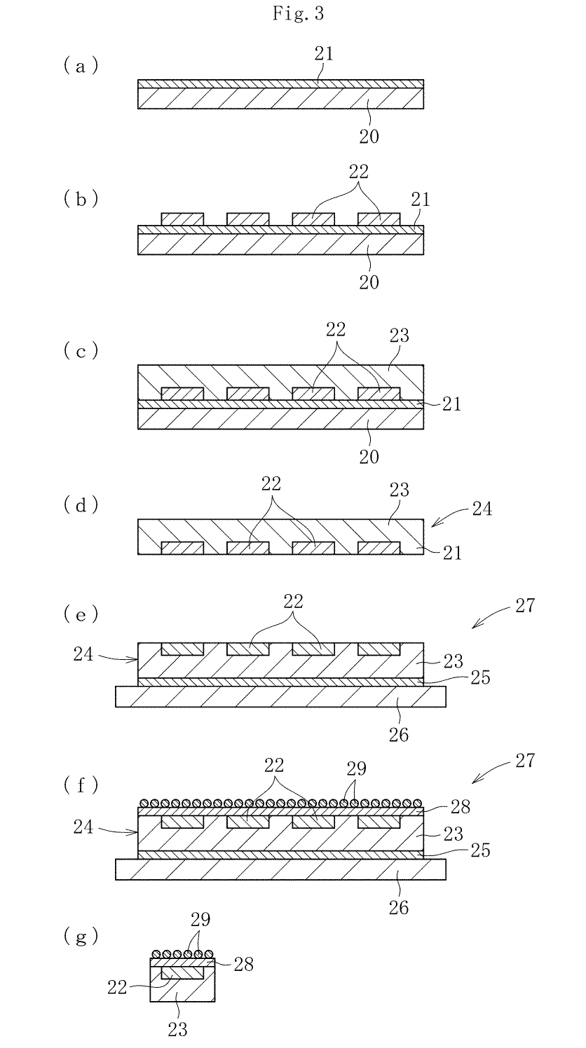

FIG. 2 is a conceptual perspective view for illustrating an example of a laminate 1 of the present invention. In FIG. 3, the laminate 1 comprises a supporting glass substrate 10 and a substrate 11 to be processed. The supporting glass substrate 10 is bonded onto the substrate 11 to be processed so as to prevent a dimensional change of the substrate 11 to be processed. A peeling layer 12 and an adhesive layer 13 are formed between the supporting glass substrate 10 and the substrate 11 to be processed. The peeling layer 12 is held in contact with the supporting glass substrate 10, and the adhesive layer 13 is held in contact with the substrate 11 to be processed.

As is understood from FIG. 2, the laminate 1 comprises the supporting glass substrate 10, the peeling layer 12, the adhesive layer 13, and the substrate 11 to be processed, which are laminated in the stated order. The shape of the supporting glass substrate 10 is determined depending on the substrate 11 to be processed, and in FIG. 3, both the supporting glass substrate 10 and the substrate 11 to be processed have a wafer shape. In the peeling layer 12, silicon oxide, a silicate compound, silicon nitride, aluminum nitride, titanium nitride, or the like may be used besides amorphous silicon (a-Si). The peeling layer 12 is formed by plasma CVD, spin coating using a sol-gel method, or the like. The adhesive layer 13 is made of a resin and is formed through application, for example, by any of various printing methods, an ink jet method, a spin coating method, a roll coating method, or the like. The adhesive layer 13 is removed by being dissolved in a solvent or the like after the supporting glass substrate 10 is peeled from the substrate 11 to be processed through use of the peeling layer 12.

FIG. 3 are conceptual sectional views for illustrating a manufacturing process for a fan-out type WLP. FIG. 3(a) is an illustration of a state in which an adhesive layer 21 is formed on one surface of a supporting member 20. As necessary, a peeling layer may be formed between the supporting member 20 and the adhesive layer 21. Next, as illustrated in FIG. 3 (b), a plurality of semiconductor chips 22 are bonded onto the adhesive layer 21. In this case, an active surface of each semiconductor chip 22 is brought into contact with the adhesive layer 21. Then, as illustrated in FIG. 3 (c), the semiconductor chips 22 are molded with a sealing material 23 of a resin. As the sealing material 23, a material having less change in dimension after compression molding and having less change in dimension during formation of wiring is used. Then, as illustrated in FIG. 3(d) and FIG. 3 (e), a substrate 24 to be processed having the semiconductor chips 22 molded therein is separated from the supporting member 20 and is adhesively fixed onto a supporting glass substrate 26 through intermediation of an adhesive layer 25. In this case, in the surface of the substrate 24 to be processed, the surface on an opposite side to the surface in which the semiconductor chips 22 are buried is arranged on the supporting glass substrate 26 side. Thus, a laminate 27 can be obtained. As necessary, a peeling layer may be formed between the adhesive layer 25 and the supporting glass substrate 26. After the obtained laminate 27 is conveyed, as illustrated in FIG. 3 (f), a wiring 28 is formed on the surface of the substrate 24 to be processed in which the semiconductor chips 22 are buried, and then a plurality of solder bumps 29 are formed. Finally, after the substrate 24 to be processed is separated from the supporting glass substrate 26, the substrate 24 to be processed is cut for each semiconductor chip 22 to be used in a later packaging step.

### EXAMPLES

### Example 1

Now, the present invention is described with reference to Examples. However, Examples below are merely examples, and the present invention is by no means limited to the following Examples.

Glass raw materials were blended so as to comprise as a glass composition, in terms of mass %, 68.9% of SiO₂, 5% of Al₂O₃, 8.2% of B₂O₃, 13.5% of Na₂O, 3.6% of CaO, 0.7% of ZnO, and 0.1% of SnO₂. After that, the resultant was loaded into a glass melting furnace to be melted at from 1,500° C. to 1,600° C. Then, the molten glass was supplied into an overflow down-draw forming apparatus to be formed to a thickness of 1.2 mm.

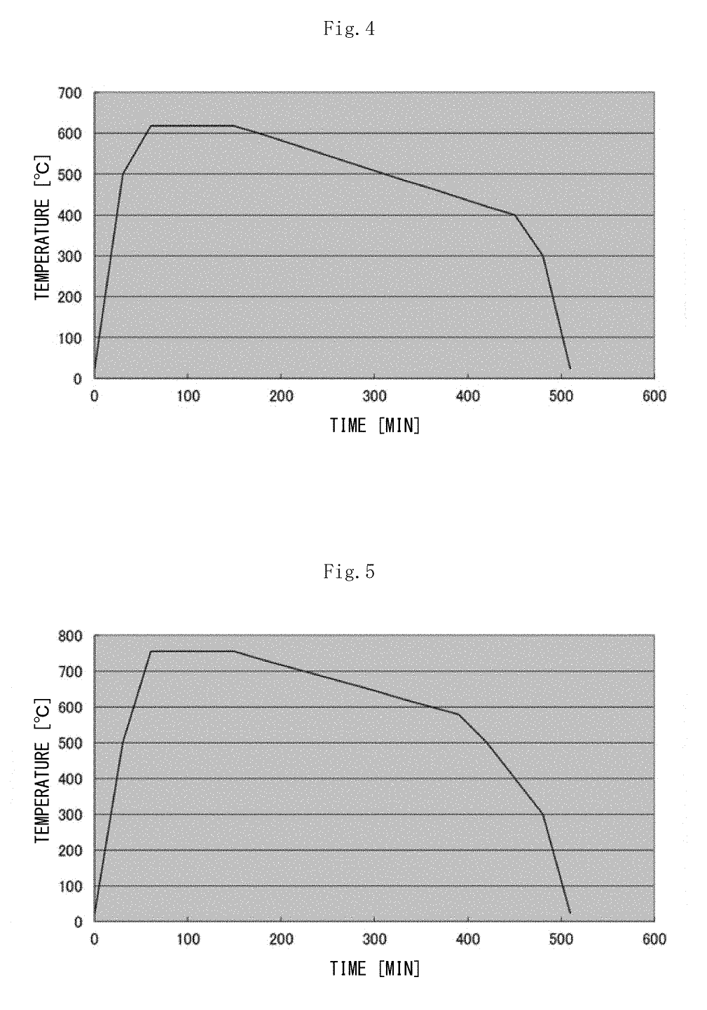

Next, the obtained mother glass sheet was cut to predetermined dimensions (30 mm×160 mm) to provide a supporting glass substrate. Further, three supporting glass substrates were laminated, and the laminated substrates were sandwiched from above and below by mullite substrates. The laminated substrates in this state were heated under a temperature increase condition shown in FIG. 4. In FIG. 4, the highest heating temperature is set to a temperature higher by 50° C. than the annealing point of the supporting glass substrate.

Subsequently, the surface of each supporting glass substrate was subjected to polishing treatment with a polishing apparatus to reduce the total thickness variation of the supporting glass substrate. Specifically, both surfaces of the supporting glass substrate were sandwiched between a pair of polishing pads having different outer diameters, and both the surfaces of the supporting glass substrate were subjected to polishing treatment while the supporting glass substrate and the pair of polishing pads were rotated together. Part of the supporting glass substrate was caused to extend off from the polishing pads intermittently during the polishing treatment. The polishing pads were made of urethane. The average particle diameter of a polishing slurry used in the polishing treatment was 2.5 μm, and the polishing speed was 15 m/min.

Finally, the temperature of the supporting glass substrate that had been subjected to heating treatment was increased from room temperature to 400° C. at a rate of 5° C./minute, kept at 400° C. for 5 hours, and decrease to room temperature at a rate of 5° C./minute, and the thermal shrinkage ratio at this time was evaluated by the numerical expression 1. For comparison, a supporting glass substrate that had not been subjected to heating treatment was also evaluated for a thermal shrinkage ratio. As a result, the supporting glass substrate that had been subjected to heating treatment had a thermal shrinkage ratio of 7 ppm, whereas the supporting glass substrate that had not been subjected to heating treatment had a thermal shrinkage ratio of 58 ppm.

### Example 2

Glass raw materials were blended so as to comprise as a glass composition, in terms of mass %, 60% of SiO₂, 16.5% of Al₂O₃, 10% of B₂O₃, 0.3% of MgO, 8% of CaO, 4.5% of SrO, 0.5% of BaO, and 0.2% of SnO₂. After that, the resultant was loaded into a glass melting furnace to be melted at from 1,550° C. to 1,650° C. Then, the molten glass was supplied into an overflow down-draw forming apparatus to be formed to a thickness of 0.7 mm.

Next, the obtained mother glass sheet was cut to a predetermined dimension (φ300 mm) to provide a supporting glass substrate. Further, three supporting glass substrates were laminated, and the laminated substrates were sandwiched from above and below by mullite substrates. The laminated substrates in this state were heated under a temperature increase condition shown in FIG. 5. In FIG. 5, the highest heating temperature is set to a temperature higher by 50° C. than the annealing point of the supporting glass substrate.

Subsequently, the surface of each supporting glass substrate was subjected to polishing treatment with a polishing apparatus to reduce the total thickness variation of the supporting glass substrate. Specifically, both surfaces of the supporting glass substrate were sandwiched between a pair of polishing pads having different outer diameters, and both the surfaces of the supporting glass substrate were subjected to polishing treatment while the supporting glass substrate and the pair of polishing pads were rotated together. Part of the supporting glass substrate was caused to extend off from the polishing pads intermittently during the polishing treatment. The polishing pads were made of urethane. The average particle diameter of a polishing slurry used in the polishing treatment was 2.5 μm, and the polishing speed was 15 m/min.

The obtained supporting glass substrate (each of 12 samples) before and after the polishing treatment was measured for a warpage level with SBW-331ML/d manufactured by Kobelco Research Institute, Inc. The results are shown in Table 1. In the measurement, the measurement pitch was set to 1 mm, the measurement distance was set to 294 mm, and the measurement line was set to 4 lines (in increments of 45°).

TABLE 1

| | Warpage level (μm) | |
|---|---|---|
| Sample | Heating treatment performed | No heating treatment performed |
| No. 1 | 18 | 137 |
| No. 2 | 17 | 179 |
| No. 3 | 14 | 129 |
| No. 4 | 20 | 126 |
| No. 5 | 20 | 116 |
| No. 6 | 19 | 146 |
| No. 7 | 16 | 152 |
| No. 8 | 21 | 147 |
| No. 9 | 17 | 159 |
| No. 10 | 20 | 149 |
| No. 11 | 19 | 134 |
| No. 12 | 10 | 201 |

As is understood from Table 1, the warpage level of the sample that had been subjected to heating treatment was 21 μm or less, whereas the warpage level of the sample that had not been subjected to heating treatment was 116 μm or more. Although the thermal shrinkage ratio of the sample that had been subjected to heating treatment was not measured, the thermal shrinkage ratio is presumed to be sufficiently low.

### Example 3

First, glass raw materials were blended so as to have a glass composition of each of Sample Nos. 1 to 7 shown in Table 2. After that, the resultant was loaded into a glass melting furnace to be melted at from 1,500° C. to 1,600° C. Then, the molten glass was supplied into an overflow down-draw forming apparatus to be formed to a thickness of 0.8 mm. After that, the mother glass sheet was cut to a predetermined dimension (φ300 mm) under the same condition as that of [Example 2], and further subjected to annealing treatment at a temperature of (the annealing point+60° C.). Each of the obtained supporting glass substrates was evaluated for an average thermal expansion coefficient α₃₀₋₃₈₀ within a temperature range of from 30° C. to 380° C., a density ρ, a strain point Ps, an annealing point Ta, a softening point Ts, a temperature at a viscosity at high temperature of 10^{4.0} dPa·s, a temperature at a viscosity at high temperature of 10^{3.0} dPa·s, a temperature at a viscosity at high temperature of 10^{2.5} dP·s, a temperature at a viscosity at high temperature of 10^{2.0} dPa·s, a liquidus temperature TL, and a Young's modulus E. After the cutting, each of the supporting glass substrates before the heating treatment was measured for a total thickness variation and a warpage level with SBW-331ML/d manufactured by Kobelco Research Institute, Inc. As a result, each total thickness variation was 3 μm, and each warpage level was 70 μm.

TABLE 2

| | | No. 1 | No. 2 | No. 3 | No. 4 | No. 5 | No. 6 | No. 7 |
|---|---|---|---|---|---|---|---|---|
| Component | SiO₂ | 65.0 | 63.2 | 65.3 | 64.0 | 60.0 | 58.4 | 61.4 |
| (wt %) | Al₂O₃ | 8.2 | 8.0 | 8.0 | 8.0 | 16.7 | 13.0 | 18.0 |
| | B₂O₃ | 13.5 | 13.1 | 8.6 | 13.3 | 9.8 | 0.0 | 0.5 |
| | MgO | 0.0 | 0.0 | 0.0 | 0.0 | 0.8 | 2.0 | 3.0 |
| | CaO | 3.3 | 3.2 | 3.2 | 3.2 | 8.0 | 2.0 | 0.0 |
| | SrO | 0.0 | 0.0 | 0.0 | 0.0 | 4.5 | 0.0 | 0.0 |
| | ZnO | 0.9 | 0.9 | 0.9 | 1.0 | 0.0 | 0.0 | 0.0 |
| | Na₂O | 8.7 | 11.3 | 13.6 | 10.1 | 0.0 | 14.5 | 14.5 |
| | K₂O | 0.0 | 0.0 | 0.0 | 0.0 | 0.0 | 5.5 | 2.0 |
| | ZrO₂ | 0.0 | 0.0 | 0.0 | 0.0 | 0.0 | 4.5 | 0.0 |
| | Sb₂O₃ | 0.1 | 0.0 | 0.1 | 0.1 | 0.0 | 0.0 | 0.0 |
| | SnO₂ | 0.3 | 0.3 | 0.3 | 0.3 | 0.2 | 0.0 | 0.7 |

| | | | | | | | |
|---|---|---|---|---|---|---|---|
| α₃₀₋₃₈₀ (×10⁻⁷/° C.) | 59 | 68 | 77 | 64 | 38 | 102 | 91 |
| ρ (g/cm³) | 2.39 | 2.43 | 2.47 | 2.41 | 2.46 | 2.54 | 2.45 |
| Ps (° C.) | 535 | 530 | 530 | 530 | 673 | 533 | 564 |
| Ta (° C.) | 570 | 565 | 565 | 565 | 725 | 576 | 613 |
| Ts (° C.) | 755 | 730 | 735 | 740 | 943 | 793 | 863 |
| 10^{4.0} dPa · s (° C.) | 1,095 | 1,050 | 1,045 | 1,065 | 1,256 | 1,142 | 1,255 |
| 10^{3.0} dPa · s (° C.) | 1,305 | 1,240 | 1,240 | 1,265 | Unmeasured | 1,319 | 1,460 |
| 10^{2.5} dPa · s (° C.) | 1,450 | 1,385 | 1,380 | 1,410 | 1,519 | 1,431 | 1,591 |
| 10^{2.0} dPa · s (° C.) | 1,640 | 1,570 | 1,540 | 1,595 | Unmeasured | Unmeasured | Unmeasured |
| TL (° C.) | 890 | 802 | 800 | 850 | Unmeasured | 880 | 970 |
| E (GPa) | 71 | 74 | 75 | 75 | 75 | 75 | 71 |

The average thermal expansion coefficient α₃₀₋₃₈₀ within a temperature range of from 30° C. to 380° C. is a value measured with a dilatometer.

The density ρ is a value measured by a well-known Archimedes method.

The strain point Ps, the annealing point Ta, and the softening point Ts are values obtained by measurement based on the method of ASTM C336.

The temperatures at viscosities at high temperature of 10^{4.0} dPa·s, 10^{3.0} dPa·s, and 10^{2.5} dPa·s are values obtained by measurement by a platinum sphere pull up method.

The liquidus temperature TL is a value obtained by loading glass powder that has passed through a standard 30-mesh sieve (500 μm) and remained on a 50-mesh sieve (300 μm) into a platinum boat, keeping the glass powder for 24 hours in a gradient heating furnace, and then measuring, by a microscopic observation, a temperature at which crystals of glass are deposited.

The Young's modulus E is a value measured by a resonance method.

Then, the surface of the supporting glass substrate was subjected to polishing treatment with a polishing apparatus. Specifically, both surfaces of the supporting glass substrate were sandwiched between a pair of polishing pads having different outer diameters, and both the surfaces of the supporting glass substrate were subjected to polishing treatment while the supporting glass substrate and the pair of polishing pads were rotated together. Part of the supporting glass substrate was caused to extend off from the polishing pads intermittently during the polishing treatment. The polishing pads were made of urethane. The average particle diameter of a polishing slurry used in the polishing treatment was 2.5 μm, and the polishing speed was 15 m/min. Each of the obtained polished supporting glass substrates was measured for a total thickness variation and a warpage level with SBW-331ML/d manufactured by Kobelco Research Institute, Inc. As a result, each total thickness variation was 0.45 μm, and each warpage level was from 10 μm to 18 μm. Further, each sample had a thermal shrinkage ratio of from 5 ppm to 8 ppm when the temperature of the sample was increased from room temperature to 400° C. at a rate of 5° C./minute, kept at 400° C. for 5 hours, and decrease to room temperature at a rate of 5° C./minute.

### REFERENCE SIGNS LIST

10, 27 laminate
11, 26 supporting glass substrate
12, 24 substrate to be processed
13 peeling layer
14, 21, 25 adhesive layer
20 supporting member
22 semiconductor chip
23 sealing material
28 wiring
29 solder bump

1. A supporting glass substrate, which has a thermal shrinkage ratio of 20 ppm or less when a temperature of the supporting glass substrate is increased from room temperature to 400° C. at a rate of 5° C./minute, kept at 400° C. for 5 hours, and decrease to room temperature at a rate of 5° C./minute.

2. The supporting glass substrate according to claim 1, wherein the supporting glass substrate has a warpage level of 40 μm or less.

3. The supporting glass substrate according to claim 1, wherein the supporting glass substrate has a total thickness variation of less than 2.0 μm.

4. The supporting glass substrate according to claim 1, wherein the supporting glass substrate has a warpage level of less than 20 μm.

5. The supporting glass substrate according to claim 1, wherein all or part of a surface of the supporting glass substrate comprises a polished surface.

6. The supporting glass substrate according to claim 1, wherein the supporting glass substrate is formed by an overflow down-draw method.

7. The supporting glass substrate according to claim 1, wherein the supporting glass substrate has a Young's modulus of 65 GPa or more.

8. The supporting glass substrate according to claim 1, wherein the supporting glass substrate has a contour of a wafer shape.

9. The supporting glass substrate according to claim 1, wherein the supporting glass substrate is used for supporting a substrate to be processed in a manufacturing process for a semiconductor package.

10. A laminate, comprising at least a substrate to be processed and a supporting glass substrate configured to support the substrate to be processed, the supporting glass substrate comprising the supporting glass substrate of claim 1.

11. A method of manufacturing a supporting glass substrate, comprising the steps of:
cutting a mother glass sheet to provide a supporting glass substrate; and
heating the supporting glass substrate to a temperature equal to or more than an annealing point of the supporting glass substrate.

12. The method of manufacturing a supporting glass substrate according to claim 11, wherein the heating is performed so that the supporting glass substrate has a thermal shrinkage ratio of 20 ppm or less when a temperature of the supporting glass substrate is increased from room temperature to 400° C. at a rate of 5° C./minute, kept at 400° C. for 5 hours, and decrease to room temperature at a rate of 5° C./minute.

13. The method of manufacturing a supporting glass substrate according to claim 11, wherein the heating is performed so that the supporting glass substrate has a warpage level of 40 μm or less.

14. The method of manufacturing a supporting glass substrate according to claim 11, further comprising forming the mother glass sheet by an overflow down-draw method.

15. The supporting glass substrate according to claim 2, wherein the supporting glass substrate has a total thickness variation of less than 2.0 μm.

16. The method of manufacturing a supporting glass substrate according to claim 12, wherein the heating is performed so that the supporting glass substrate has a warpage level of 40 μm or less.
